(19) United States
(12) Patent Application Publication
(10) Pub. No.: US 2008/0156372 A1
(43) Pub. Date: Jul. 3, 2008

(54) THIN FILM SOLAR CELL MODULE OF SEE-THROUGH TYPE AND METHOD OF FABRICATING THE SAME

(75) Inventors: Jian-Shu Wu, Yunlin County (TW); Yih-Rong Luo, Taoyuan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: INDUSTRIAL TECHNOLOGY RESEARCH INSTITUTE, Hsinchu (TW)

(21) Appl. No.: 11/682,319

(22) Filed: Mar. 6, 2007

(30) Foreign Application Priority Data
Dec. 29, 2006 (TW) 95149988
Feb. 8, 2007 (TW) 96104570

(51) Int. Cl. H01L 31/00

(52) U.S. Cl. 136/260; 136/252; 136/261; 136/262; 136/263; 136/264; 136/265

(57) ABSTRACT

A thin film solar cell module of see-through type and a method of fabricating the same are provided. First, bi-directional openings are formed in the transparent electrode material layer to avoid problems that affect the production yield such as short-circuit resulted by the high-temperature laser scribing process. Moreover, the thin film solar cell module of see-through type has openings that expose the transparent substrate without covering the transparent electrode material layer to increase the transmittance of the cells.

### CROSS-REFERENCE TO RELATED APPLICATION

This application claims the priority benefits of Taiwan application serial nos. 95149988, filed on Dec. 29, 2006 and 96104570, filed on Feb. 8, 2007. All disclosures of the Taiwan applications are incorporated herein by reference.

### BACKGROUND OF THE INVENTION

1. Field of the Invention

The present invention relates to a photovoltaic module and the method for fabricating the same, and more particularly, to a thin film solar cell module of see-through type and the method for fabricating the same.

2. Description of Related Art

Solar energy is a renewable energy that is clean, which means it does not cause pollution. It has been the main focus in the development of green (i.e., environmental-friendly) energy as an attempt to counter the problems such as pollution and shortage faced by fossil fuels. Herein, solar cells are used to directly convert solar energy into electrical energy, which has been a very important topic in the development of renewable energy.

Currently, monocrystalline silicon and poly- or multicrystalline silicon solar cells account for more than 90% of the solar cell market. However, manufacturing these types of solar cells requires using silicon wafers that are approximately 150 μm to 350 μm thick, which increase the manufacturing costs. The production of solar cells requires high-grade silicon. Up to 2004 this silicon was obtained from overcapacity in the semiconductor industry. Recently, however, the demand for high-grade silicon—so called feedstock—from the solar energy industry began to outstrip production capacity. This tight market has resulted in a significant price increase of feedstock. Companies lacking a contract for forward delivery could not obtain any silicon at all. The thin film solar cell can be made extremely thin. The thickness of a-Si cell is 0.3 μm, which is 1/600 of that of crystalline silicon cell (approx. 200 μm). This means that a-Si cell less material and energy thereby enabling high productivity for mass production. Hence, thin film solar cells have become the main focus in the research and development of solar energy. Moreover, thin film solar cells are less expensive to manufacture, easier to manufacture in large quantities and the module fabrication thereof is simple.

FIG. 1 schematically illustrates a conventional thin film solar cell module. As shown in FIG. 1, a thin film solar cell module 150 includes a glass substrate 152, a transparent electrode 154, a photoelectric conversion layer 156 and a metal electrode 158. Herein, the transparent electrode 154 is disposed on the glass electrode 152. The photoelectric conversion layer 156 is disposed on the transparent electrode 154 by position displacement. In addition, the metal electrode 158 is disposed on the photoelectric conversion layer 156 by position displacement and is in contact with the underlying transparent electrode 154. In the thin film solar cell module 150, the photoelectric conversion layer 156 usually includes a p-i-n structure composing of a p-type semiconductor, an intrinsic semiconductor and an n-type semiconductor. Usually, light is transmitted though the bottom of the glass substrate 152 and is absorbed by the photoelectric conversion layer 156 to generate electron-hole pairs. Further, the electron-hole pairs will be separated by the electric field established across the device to form voltage and electrical current, which are transmitted by the conductive wire for loading. To enhance the efficiency of cells in the conventional thin film solar cell module 150, pyramid-like structures or textured structures (not shown) are formed on the surface of the transparent electrode 154 to reduce reflection of light. The photoelectric conversion layer 156 is usually fabricated using amorphous silicon thin film. However the band gap for amorphous silicon thin film is usually between 1.7 eV and 1.8 eV, which absorbs wavelength of sunlight that is less than 800 nm. To increase the utility of light, usually a layer of micro-crystalline or nano-crystalline thin films is stacked on the amorphous thin film, forming a p-i-n/p-i-n tandem solar cell. The bandgap of micro-crystalline or nano-crystalline is usually between 1.1 eV and 1.2 eV, which absorbs wavelength of sunlight that is less than 1,100 nm.

In the early times, the manufacturing of solar cells was costly and difficult, and solar cells were only used in special fields such as astronautics. At present, solar cells have become more widely used and applied through utilizing its ability to converting solar energy into electrical energy. The application of solar cells ranges from use in apartments and high-rise buildings to that in camper vans and portable refrigerators. However, silicon wafer-based solar cells are not suitable in certain applications such as transparent glass curtain and other building integrated photovoltaic (BIPV). Thin film solar cells of see-through type are used in the aforementioned applications because they are energy-efficient and attractive. Further, they accommodate more readily with day-to-day living demands.

Currently, some techniques related to thin film solar cells of see-through type and the method of fabricating the same have been disclosed in some U.S patents.

U.S. Pat. No. 6,858,461 provides a partially transparent photovoltaic module. As shown in FIG. 2, a photovoltaic module 110 includes a transparent electrode 114, a transparent conductive layer 118, a metal electrode 122 and a photoelectric conversion layer disposed between the transparent conductive layer 118 and the metal electrode 122. Similarly, light is transmitted through the bottom of the transparent electrode 114. In the photovoltaic module 110, a laser scribing process is performed to remove a portion of the metal electrode 122 and a portion of the photoelectric conversion layer to form at least one groove 140 to achieve transparency for the photovoltaic module 110. However, the laser scribing process is performed at a high temperature. Due to such a high temperature, the metal electrode 122 can thus easily form metal residues or melt down and accumulate in the grooves or trenches, resulting in short-circuit of the top and bottom electrodes. On the other hand, amorphous silicon photoelectric conversion layer can recrystallize at such a high temperature, forming low resistant micro-crystalline or nano-crystalline silicon on the sidewalls of the groove. Consequently, current leakage is increased, and the production yield and the efficiency of the solar cells are affected. Nevertheless, pyramid-like structures or textured structures are usually formed on the surface of the transparent conductive layer 118 to enhance the efficiency of the cells. However, light transmittance is not effectively enhanced because the light transmitted through the bottom of the transparent substrate 114 is scattered.

In view of the above, greater portions of the metal electrode and photoelectric conversion layer must be removed for solar cells to achieve a certain level of light transmittance. Please refer to Table 1. The table lists the technical specifications of the various thin film cells of see-through type manufactured by MakMax Taiyo Kogyo (Japan). According to Table 1, to enhance light transmittance, larger portions of the metal electrode and photoelectric conversion layer must be removed to decrease the maximum output, efficiency and fill factor (FF).

TABLE 1

| | Type | | |
|---|---|---|---|
| | KN-38 | KN-45 | KN-60 |
| Size(mm) | 980 × 950 | 980 × 950 | 980 × 950 |
| Transmittance (%) | 10 | 5 | <1 |
| Maximum Power Output (W) | 38.0 | 45.0 | 58.0 |
| Vpm (V) | 58.6 | 64.4 | 68.0 |
| Ipm (A) | 0.648 | 0.699 | 0.853 |
| Voc (V) | 91.8 | 91.8 | 91.8 |
| Isc (A) | 0.972 | 1.090 | 1.140 |
| Efficiency (%) | 4.1 | 4.8 | 6.2 |
| Fill Factor (FF) | 0.43 | 0.45 | 0.55 |

Moreover, a photovoltaic device is disclosed in U.S. Pat. No. 4,795,500. As shown in FIG. 3, a photovoltaic device includes a transparent substrate 1, a transparent conductive layer 3, a photoelectric conversion layer 4, a metal electrode 5 and a resist layer 8. In the photovoltaic device, holes 6 are formed in the metal electrode 5, the photoelectric conversion layer 4 and even in the transparent conductive layer 3 to achieve transparency. Nevertheless, this patent utilizes the lithographic process which adds on to the manufacturing costs since the related facility is rather expensive. Additionally, this patent utilizes the laser scribing process to directly form holes 6, which will result in metal residues contamination and short-circuit, affecting the production yield.

### SUMMARY OF THE INVENTION

Accordingly, the present invention provides a thin film solar cell module of see-through type and the method for fabricating the same that can increase the light transmittance of the cell module and overcome the disadvantages such as short-circuit and current leakage encountered by the conventional fabrication method to improve the production yield and the efficiency of the solar cell.

The present invention provides a method for fabricating a thin film solar cell module of see-through type that includes the following steps. First, a first electrode material layer is formed on a transparent substrate. Next, a portion of the first electrode material layer is removed to form a plurality of first Y-directional openings, which divide the first electrode material layer into a plurality of banding electrode material layers. Further, a plurality of first X-directional openings are formed to intersect with the plurality of the first Y-directional openings, which further divide the first electrode material layer into a first comb electrode and a two-dimensional array of multiple first electrodes. Then, a photoelectric conversion layer is formed to cover the transparent substrate, the first electrodes and a portion of the first comb electrode. Afterward, a portion of the photoelectric conversion layer is removed to form a plurality of second Y-directional openings which are parallel to the first Y-directional openings above the first electrode. Thereafter, a second electrode material layer is formed to cover the photoelectric conversion layer, the first electrode and the transparent electrode. Following that, a portion of the second electrode material layer and a portion of the photoelectric conversion layer are removed to form a plurality of third Y-directional openings that expose the surface of the first electrode. Further, a plurality of second X-directional openings is formed in the first X-directional openings to divide the second electrode material layer into a second comb electrode and a two-dimensional array of multiple second electrodes.

The present invention provides another thin film solar cell module of see-through type having a plurality of cells connected in series. A plurality of openings are formed among the cells to expose a transparent substrate. The thin film solar cell module of see-through type includes a first electrode, a second electrode and a photoelectric conversion layer. Herein, the first electrode is disposed on the transparent substrate and the first electrode is composed of a first comb electrode and a two-dimensional array of multiple first electrodes. The second electrode is disposed above the first electrode and the second electrode is composed of a second comb electrode and a two-dimensional array of multiple second electrodes. The second comb electrode and the first comb electrode are disposed symmetrically and the first electrode and the second electrode are disposed by parallel displacement. The photoelectric conversion layer is disposed between the first electrode and the second electrode. The photoelectric conversion layer is composed of a two-dimensional array of multiple photoelectric conversion material layers.

The present invention provides yet another method for fabricating a thin film solar cell module of see-through type. First, a first electrode material layer is formed on a transparent substrate. Next, a portion of the first electrode material layer is removed to form a plurality of first Y-directional openings, which divide the first electrode material layer into a plurality of banding electrode material layers. Further, a plurality of first X-directional openings is formed to intersect with the plurality of the first Y-directional openings, which further divide the first electrode material layer into a plurality of first window electrodes. Afterward, a photoelectric conversion layer is formed to cover the first window electrodes and the transparent substrate. Thereafter, a portion of the photoelectric conversion layer is removed to form a plurality of second Y-directional openings that are parallel to the first Y-directional openings above the first window electrodes. A second electrode material layer is formed on the photoelectric conversion layer. Following that, a portion of the second electrode material layer and a portion of the photoelectric conversion layer are removed to form a plurality of third Y-directional openings that expose the surface of the first window electrodes. Further, a plurality of second X-directional openings is formed in the first X-directional openings to divide the second electrode material layer into a plurality of second window electrodes.

The present invention provides yet another thin film solar cell module of see-through type having a plurality cells connected in series in the X-direction and connected in parallel in the Y-direction. A plurality of openings are formed among the cells to expose a transparent substrate. The thin film solar cell module of see-through type includes a first electrode, a second electrode, and a photoelectric conversion layer. Herein, the first electrode is formed on the transparent substrate and the first electrode is composed of a plurality of first window electrodes. The second electrode is disposed on the first electrode and the second electrode is composed of a plurality of second window electrodes. The second window electrodes and the first window electrodes are arranged by parallel displacement. Further, the photoelectric conversion layer is disposed between the first electrode and the second electrode. The photoelectric conversion layer is composed of a plurality of window photoelectric conversion material layers.

According to the thin film solar cell module of see-through type and the method for fabricating the same of the present invention, bi-directional openings are formed during the formation of the first electrode. As a result, the thin film solar cell module of see-through type fabricated according to the present invention can overcome the problems such as short-circuit and current leakage resulted by the high-temperature laser scribing process. Hence, the production yield and the efficiency of the solar cell are improved. Further, in contrast to the conventional thin-film solar cell module of see-through type, the present invention teaches openings that can expose the transparent substrate which avoids scattering of light due to the formation of pyramid-like structures or textured structure on the surface of the transparent oxide electrode. Consequently, the light transmittance of the device is greatly increased.

In order to the make the aforementioned and other objects, features and advantages of the present invention comprehensible, a preferred embodiment accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 schematically illustrates a conventional thin film solar cell module.

FIG. 2 schematically illustrates a conventional photovoltaic module.

FIG. 3 schematically illustrates a conventional photovoltaic device.

FIG. 4 through FIG. 9 schematically illustrates the steps for fabricating a thin film solar cell module of see-through type according to one embodiment of the present invention. Herein, the sub-diagrams (a) for FIG. 4 through FIG. 9 are schematic top views of FIG. 4 through FIG. 9. The sub-diagrams (b) and (b′) for FIG. 4 through FIG. 9 are schematic cross-sectional views along the line I-I′. The sub-diagrams (c) for FIG. 4 through FIG. 9 are schematic cross-sectional views along the line II-II′.

FIG. 10 through FIG. 15 schematically illustrates the steps for fabricating a thin film solar cell module of see-through type according to another embodiment of the present invention. Herein, the sub-diagrams (a) for FIG. 10 through FIG. 15 are schematic top views of FIG. 10 through FIG. 15. The sub-diagrams (b) for FIG. 10 through FIG. 15 are schematic cross-sectional views along the line I-I′. The sub-diagrams (c) for FIG. 10 through FIG. 15 are schematic cross-sectional views along the line II-II′.

FIG. 16 is a graph illustrating the relationship between the transmittance through transparent electrodes of varying thickness disposed on the glass substrate and different wavelengths.

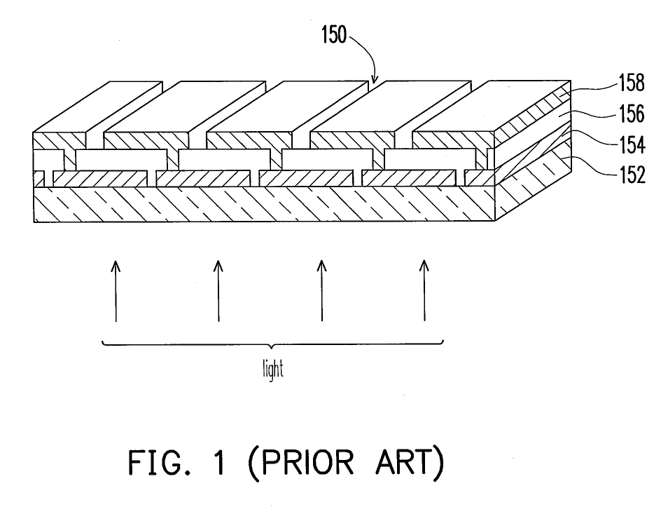

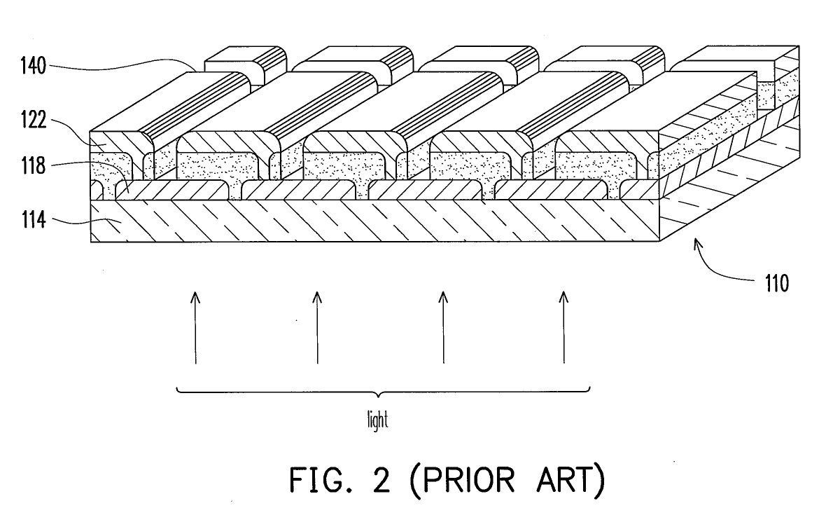

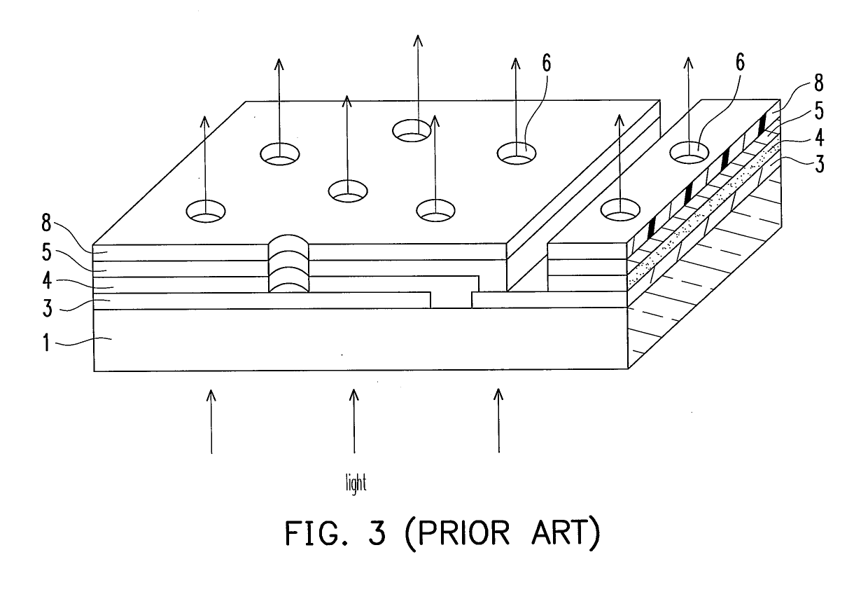

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

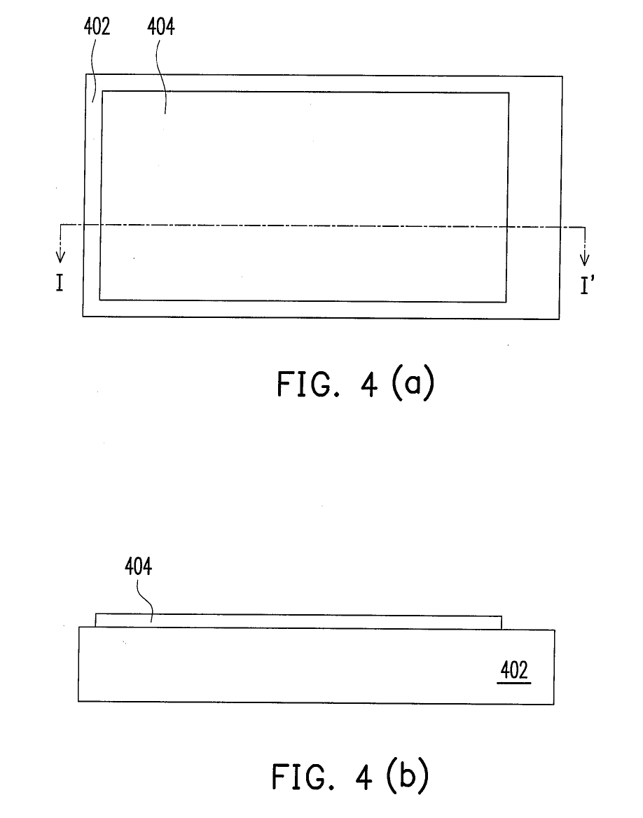

FIG. 4 through FIG. 9 schematically illustrates the process for fabricating a thin film solar cell module of see-through type according to one embodiment of the present invention. Herein, the sub-diagrams (a) for FIG. 4 through FIG. 9 are schematic top views of FIG. 4 through FIG. 9. The sub-diagrams (b) and (b′) for FIG. 4 through FIG. 9 are schematic cross-sectional views along the line I-I′. The sub-diagrams (c) for FIG. 4 through FIG. 9 are schematic cross-sectional views along the line II-II′.

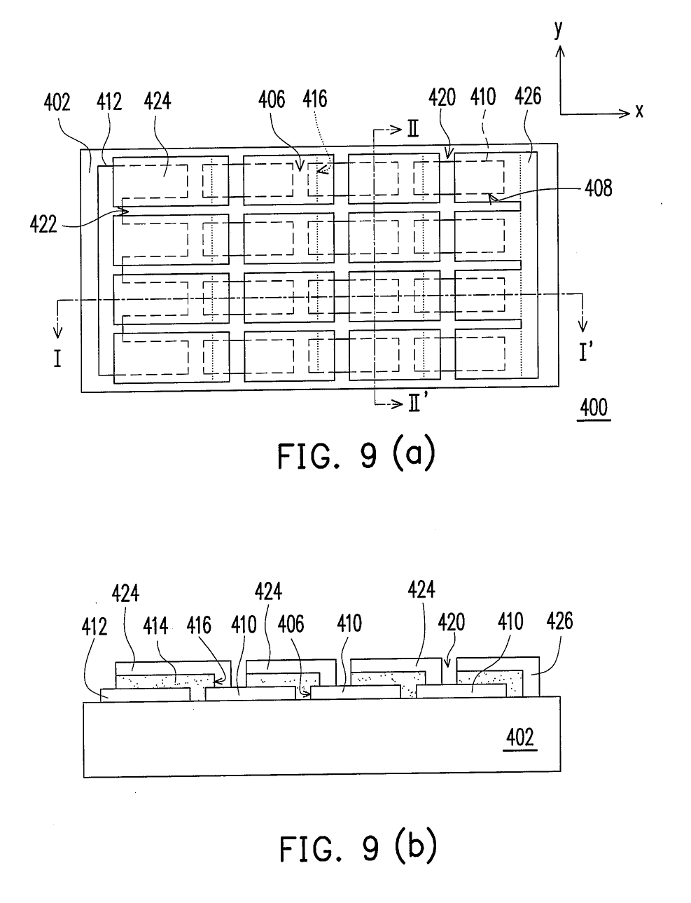

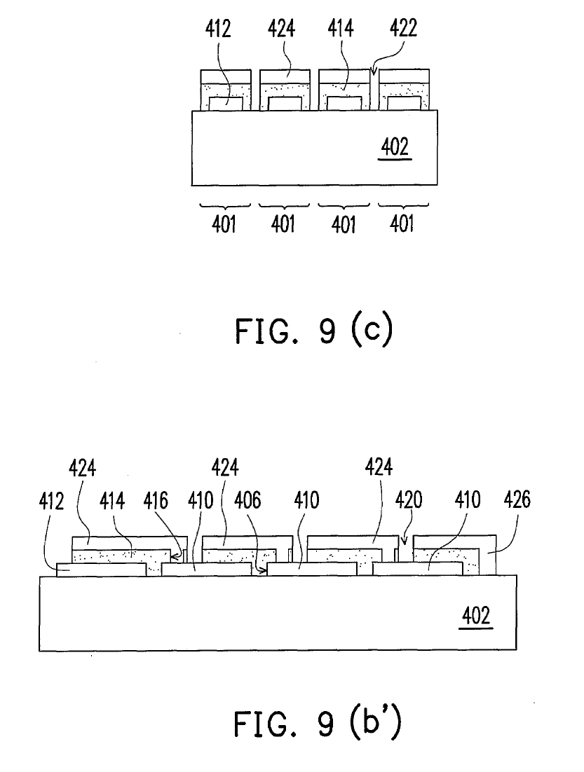

First, please refer to FIG. 9 (a), FIG. 9 (b), FIG. 9 (b′), and FIG. 9 (c). A thin film solar cell module of see-through type 400 of the present embodiment is composed of a plurality of cells 401 connecting in series. Moreover, a plurality of X-directional openings 422 and a plurality of Y-directional openings 420 which expose a transparent substrate 402 are formed among these cells. Therefore, when light (sun light) is transmitted through the bottom of the transparent substrate 402, it can penetrate through the X-directional openings 422 and the Y-directional openings 420 to achieve transparency for the thin-film solar cell module of see-through type 400.

The thin-film solar cell module of see-through type 400 includes the transparent substrate 402, a transparent electrode disposed above the transparent substrate 402, a metal electrode and a photoelectric conversion layer 414. Herein, the transparent electrode is directly disposed on the transparent substrate 402, which is composed of a comb electrode 412 and a two-dimensional array of multiple electrodes 410. The metal electrode is disposed above the transparent electrode, which is composed of a comb electrode 426 and a two-dimensional array of multiple electrodes 424. Moreover, the comb electrodes 412 and 426 are disposed symmetrically while the electrodes 410 and 424 are arranged by parallel displacement. Furthermore, the photoelectric conversion layer 414 is disposed between the transparent electrode and the metal electrode and the photoelectric conversion layer 414 is composed of a two-dimensional array of multiple photoelectric conversion material layers.

It should be noted that the thin film solar cell module of see-through type 400 in the present embodiment has openings, X-directional openings 422, which can expose the transparent substrate 402, to further improve the transparency for the cell module. Therefore, in contrast to the conventional thin film solar cell module of see-through type, the thin film solar cell module of see-through type 400 in the present embodiment has a better light transmittance for the device.

On the other hand, as shown in FIG. 9 (c), since the transparent electrode is covered by the photoelectric conversion layer 414, after high-temperature laser scribing process, the production of metal residues or molten metal that will not come into direct contact with the transparent electrode during the formation of the X-directional openings 422. Hence, problems that affect the production yield and the efficiency of the solar cell like short-circuit or current leakage resulted by recrystallization of the amorphous silicon photoelectric conversion layer on the sidewalls of the grooves to produce low resistant micro-crystalline or nano-crystalline silicon can be avoided.

FIG. 4 through FIG. 9 are used to further illustrate the method for fabricating the thin film solar cell module of see-through type 400 according to the present embodiment as follows.

First, in FIGS. 4(a) and 4(b), a transparent substrate 402 is provided. The material of the transparent substrate 402 is, for example, glass or other suitable transparent materials. Next, a electrode material layer 404 is formed on the transparent substrate 402. The electrode material layer 404 is a transparent conductive oxide thin film, and the material thereof is, for example, ZnO, SnO₂, ITO or In₂O₃. The forming method of the electrode material layer 404 is, for example, a chemical vapor deposition, a sputtering process or other suitable fabrication method.

Certainly, the surface of the electrode material layer can be textured to enhance the efficiency of the cell by reducing the reflection of light. Nevertheless, texturing the surface will result in uneven surface that leads to the scattering of light, reducing the reflection of incident light, and increasing the distance traveled by the incident light in the photoelectric conversion layer. Therefore, textured structures (uneven surface), pyramid-like structures (not shown) or inverted pyramid-like structures are usually formed on the surface of the electrode material layer instead.

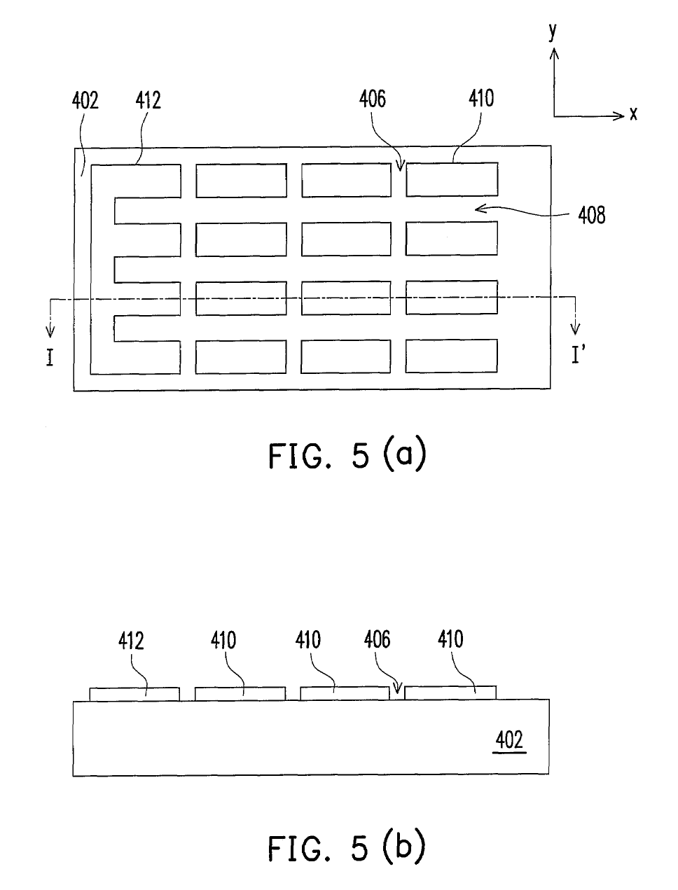

Please refer to FIGS. 5(a) and 5(b). A portion of the electrode material layer 404 is removed to form a plurality of Y-directional openings 406 and a plurality of X-directional openings 408 that intersect with the plurality of Y-directional openings 406. Herein, the electrode material layer 404 can be divided into a plurality of banding electrode material layers (not shown) during the formation of the Y-directional openings 406. After the formation of the Y-directional openings 406 and the X-directional openings 408, the electrode material layer 404 can be divided into a comb electrode 412 and a two-dimensional array of multiple electrodes 410. Accordingly, the method for forming the Y-directional openings 406 and the X-directional openings 408 is, for example, removing a portion of the electrode material layer 404 by a laser scribing process.

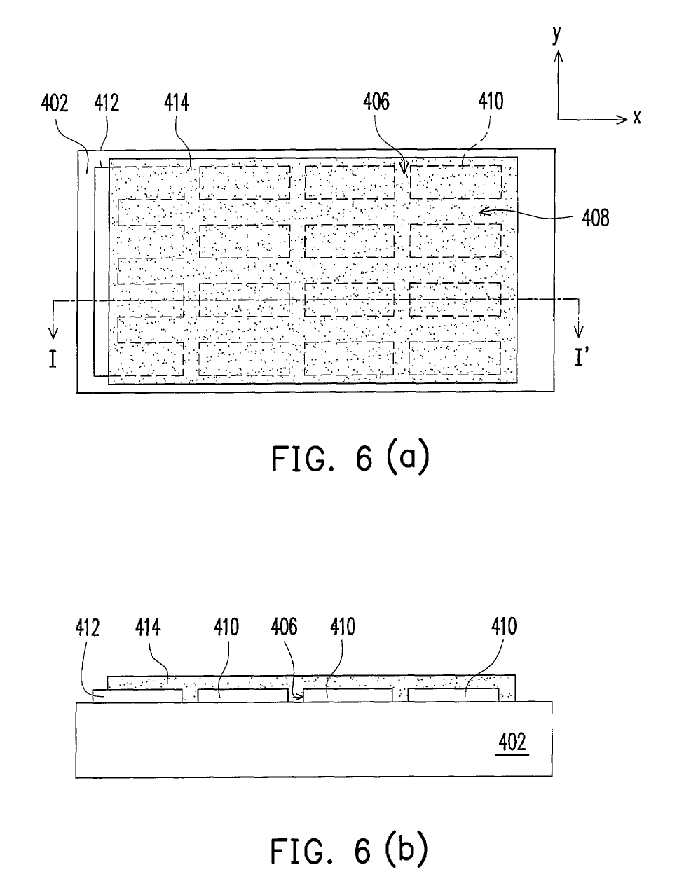

Please refer to FIGS. 6(a) and 6(b), a photoelectric conversion layer 414 is formed above a transparent substrate 402. The transparent substrate 402, the electrode 410 and a portion of the comb electrode 412 will be covered by the photoelectric conversion layer 414. The photoelectric conversion layer 414 can be a single-layered structure or a multi-layered structure. The photoelectric conversion layer can be fabricated using materials such as amorphous silicon and amorphous silicon alloy, CdS, CulnGaSe₂ (CIGS), CulnSe₂ (CIS), CdTe, organic material or a multi-layered structure comprising the aforementioned materials. The method for forming the photoelectric conversion layer 414 is, for example, a chemical vapor deposition, a sputtering process or other suitable fabrication method. Further, it should be noted that the above-mentioned amorphous silicon alloy refers to amorphous silicon with the addition of elements such as H, F, Cl, Ge, O, C or N. Adding elements such as H, F, and Cl to amorphous silicon can repair the defects in the silicon thin film to obtain a better thin film quality. However, adding elements such as Ge to amorphous silicon can decrease the band gap of the silicon thin film to absorb longer wavelength of sunlight. On the other hand, adding elements such as oxygen, carbon, and nitrogen to amorphous silicon can increase the band gap of the silicon thin film to absorb shorter wavelength of sunlight.

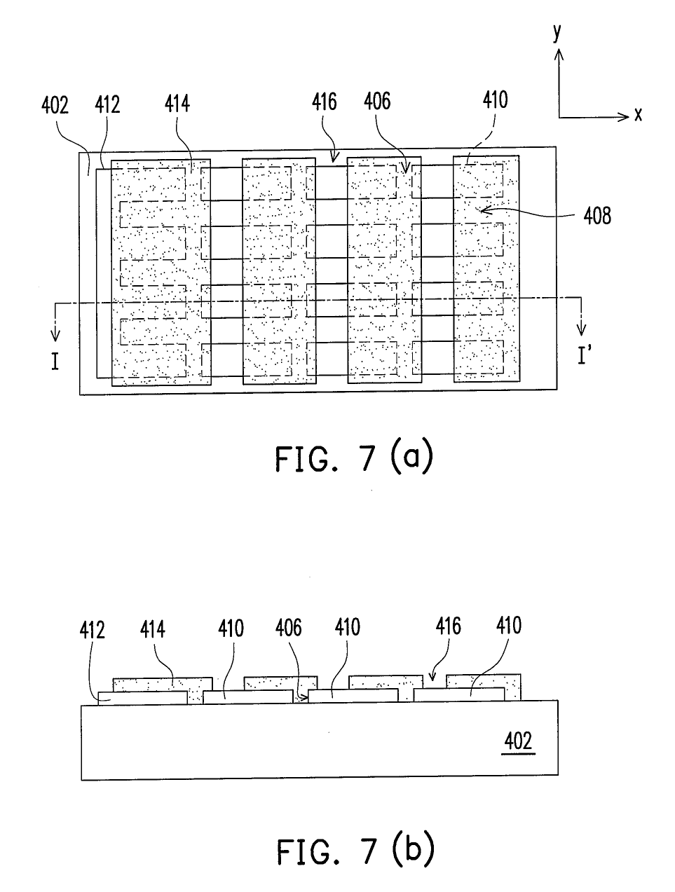

Please refer to FIGS. 7(a) and 7 (b). A portion of the photoelectric conversion layer 414 is removed to form a plurality of Y-directional openings 416. These Y-directional openings 416 are formed on the electrode 410 and are parallel to the Y-directional openings 406. The method for forming the Y-directional openings 416 is, for example, removing a portion of photoelectric conversion layer 414 by a laser scribing process.

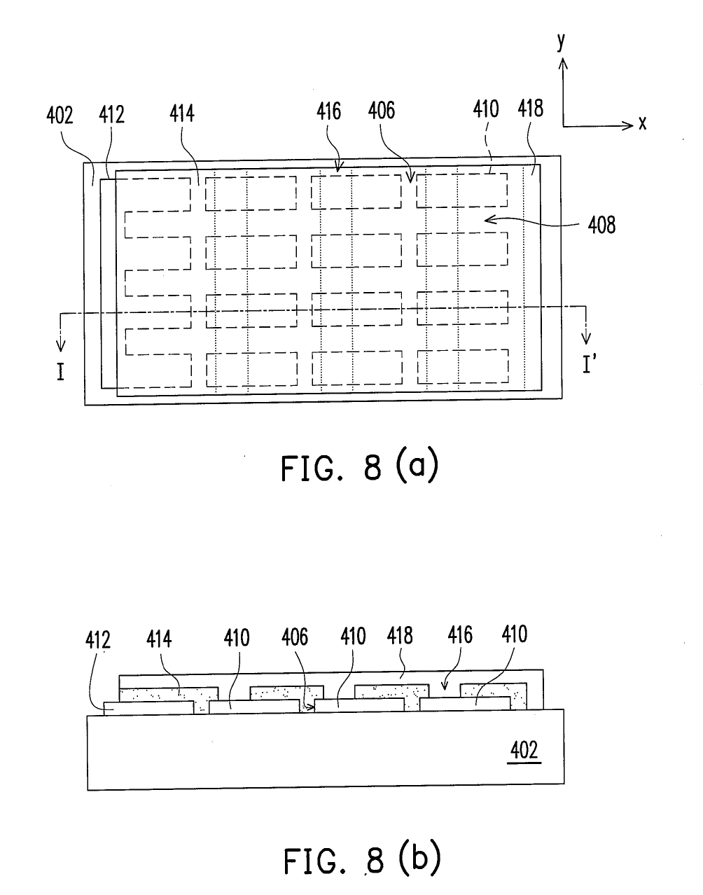

Please refer to FIGS. 8 (a) and 8(b), an electrode material layer 418 is formed above the transparent substrate 402. The photoelectric conversion layer 414, the electrode 410 and the transparent electrode 402 will be covered by the electrode material layer 418. The electrode material layer 418 is a metal layer which material is Al, Ag, Mo, Cu or other suitable metal or metal alloys, for example. The method for forming the photoelectric conversion layer 418 is, for example, chemical vapor deposition, sputtering process or other appropriate fabrication method.

Please refer FIGS. 9 (a), 9 (b), 9(b′) and 9 (c), a plurality of Y-directional openings 420 and a plurality of X-directional openings 422 that intersect to the Y-directional openings 420 are formed to divide the electrode material layer 418 into a comb electrode 426 and a two-dimensional array of multiple electrodes 424. Herein, the X-directional openings 422 are formed by removing a portion of the electrode material layer 418 in the X-directional openings 408 and a portion of photoelectric conversion layer 414 to expose the surface of the transparent substrate 402. Further, the Y-directional openings 420 are formed by removing a portion of the electrode material layer 418 in the Y-directional openings 416 until exposing the surface of the electrode 410. As shown in FIG. 9(b′), the Y-directional openings 420 can also be formed on the openings 416 by position displacement, and can be formed by removing a portion of electrode material layer 418 and a portion of photoelectric conversion layer 414 until exposing the surface of the electrode 410. Similarly, the Y-directional openings 420 and the X-directional openings 422 are formed by removing a portion of electrode material layer 418 and a portion of the photoelectric conversion layer 414 using laser scribing process. The thin film solar cell module of see-through type 400 in the present embodiment is completed after each step as mentioned above has been performed.

In addition, the thin film solar cell module of see-through type 400 of the present embodiment can be fabricated using other methods. For example, during the formation of Y-directional openings 416 in the photoelectric conversion layer 414 (as shown in FIGS. 7(a) and 7(b)), a plurality of X-directional openings (not shown) that intersect with the Y-directional openings 416 can also be formed to divide the photoelectric conversion layer 414 into a plurality of photoelectric conversion layers (not shown). The steps that follow would be similar to the aforementioned embodiment. Detailed description thereof is thus omitted.

In addition to the above-mentioned embodiments, the present invention also provides other implementations.

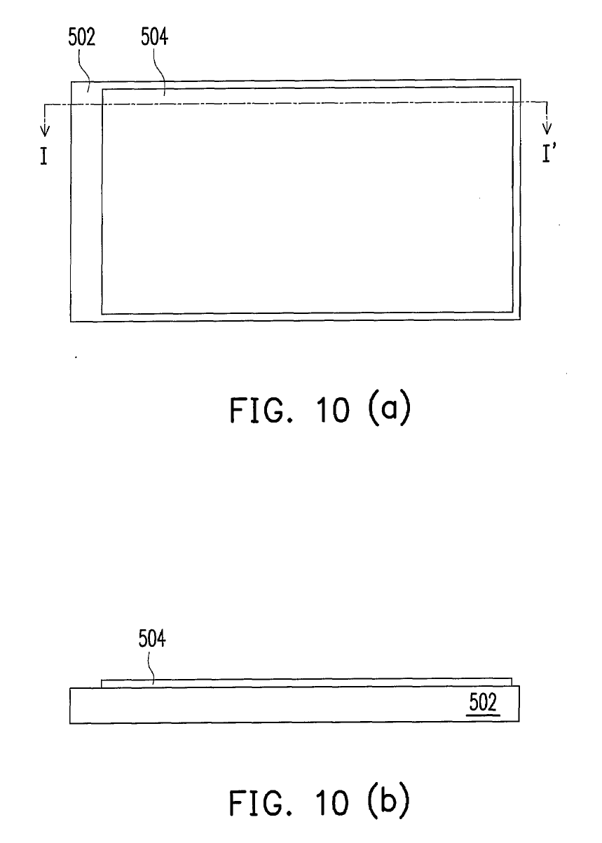

FIG. 10 through FIG. 15 schematically illustrates the steps for fabricating a thin film solar cell module of see-through type according to another embodiment of the present invention. Herein, the sub-diagrams (a) for FIG. 10 through FIG. 15 are schematic top views of FIG. 10 through FIG. 15. The sub-diagrams (b) for FIG. 10 through FIG. 15 are schematic cross-sectional views along the line I-I′. The sub-diagrams (c) for FIG. 10 through FIG. 15 are schematic cross-sectional views along the line II-II′. Some elements appeared in FIG. 10 through FIG. 15 are similar to those appeared in FIG. 4 through FIG. 9. Thus, detailed description thereof is omitted.

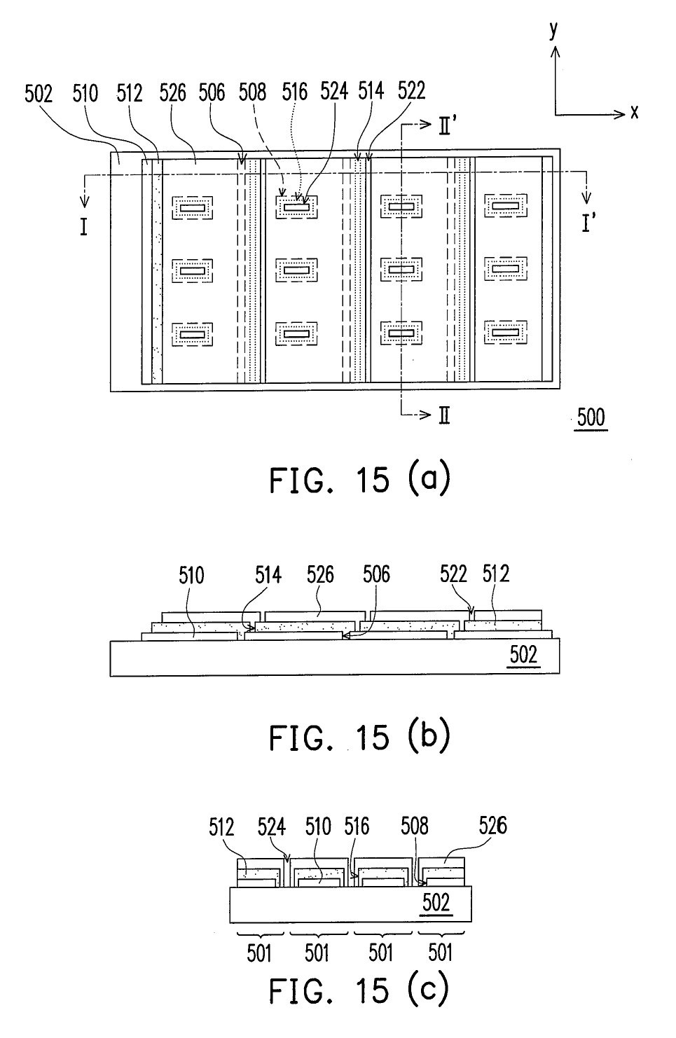

First, please refer to FIGS. 15 (a), 15 (b) and 15 (c). A thin film solar cell module of see-through type 500 of the present embodiment has a plurality of cells 501 that are connected in series in the X-direction and are connected in parallel in the Y-direction. Further, a plurality of X-directional openings 524 that expose a transparent substrate 502 among these cells 501. When light (sun light) is transmitted through the bottom of the transparent substrate 502, it can penetrate through the X-directional openings 524 to achieve transparency for the thin-film solar cell module of see-through type 500.

The thin film solar cell module of see-through type 500 includes the transparent substrate 502, a transparent electrode disposed on the transparent substrate 502, a metal electrode and a photoelectric conversion layer 512. Herein, the transparent electrode disposed on the transparent substrate 502 is composed of a plurality of window electrodes 510. The metal electrode disposed on the transparent electrode is composed of a plurality of window electrodes 526. Further, comb window electrodes 510 and 526 are arranged by parallel displacement. Moreover, the photoelectric conversion layer 512 is disposed between the transparent electrode and the metal electrode. The photoelectric conversion layer 512 is composed of a plurality of window photoelectric conversion material layers.

The thin film solar cell module of see-through type 500 of the present embodiment has openings, X-directional openings 524, which can expose the transparent substrate 402 to improve the transparency for the cell module. Therefore, in contrast to the conventional thin film solar cell module of see-through type, the thin film solar cell module of see-through type according to the present embodiment can achieve a better light transmittance for the device. Additionally, as shown in FIG. 15 (c), since the transparent electrode will be covered by the photoelectric conversion layer 512, problems that affect the production yield and the efficiency of the solar cell such as short-circuit or current leakage resulted by metal residues or molten metal that comes into contact with the transparent electrode when fabricating the X-directional openings 524 using a high-temperature laser scribing process can be avoided.

FIG. 10 through FIG. 15 are used to further illustrate the method for fabricating the thin film solar cell module of see-through type 500 according to the present embodiment as follows.

First, in FIGS. 10(a) and 10(b), a transparent substrate 502 is provided. The material of the transparent substrate 502 is, for example, glass or other suitable transparent materials. Next, a first electrode material layer 504 is formed on the transparent substrate 502. The electrode material layer 504 is a transparent conductive oxide layer.

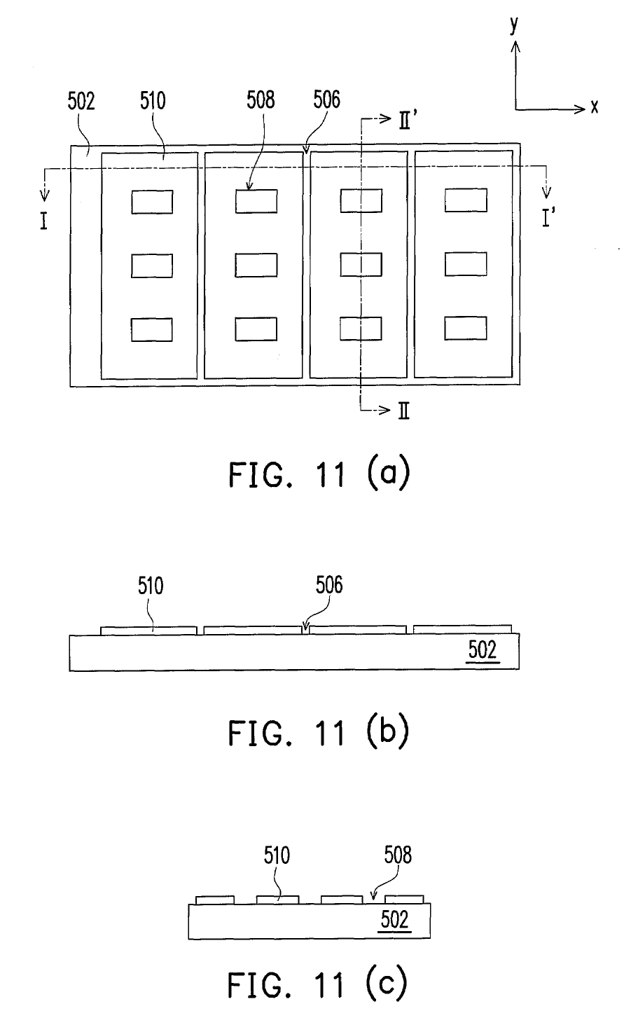

In FIGS. 11(a), 11(b) and 11(c), a plurality of Y-directional openings 506 are formed in the electrode material layer 504, which divides the electrode material layer 504 into a plurality of banding electrode material layers. Further, a two-dimensional array of multiple X-directional openings 508 are formed intersect with the Y-directional openings 506. The Y-directional openings 506 and the X-directional openings 508 can divide the electrode material layer 504 into a plurality of window electrodes 510.

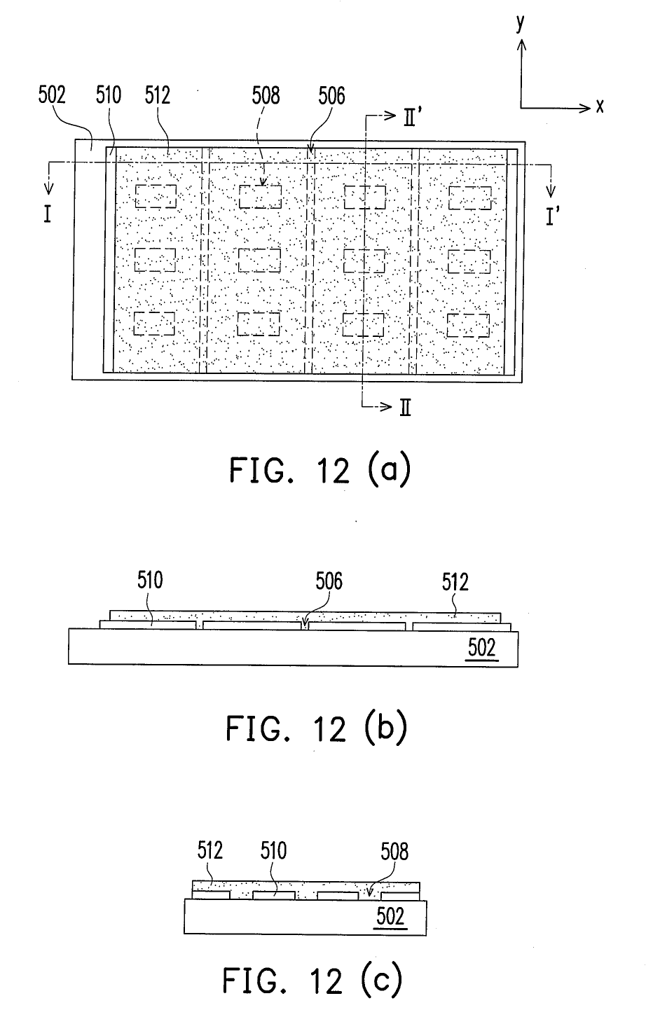

Please refer to FIGS. 12(a), 12(b) and 12(c), a photoelectric conversion layer 512 is formed above the transparent substrate 502. The transparent substrate 502 and the window electrode 510 will be covered by the photoelectric conversion layer 512.

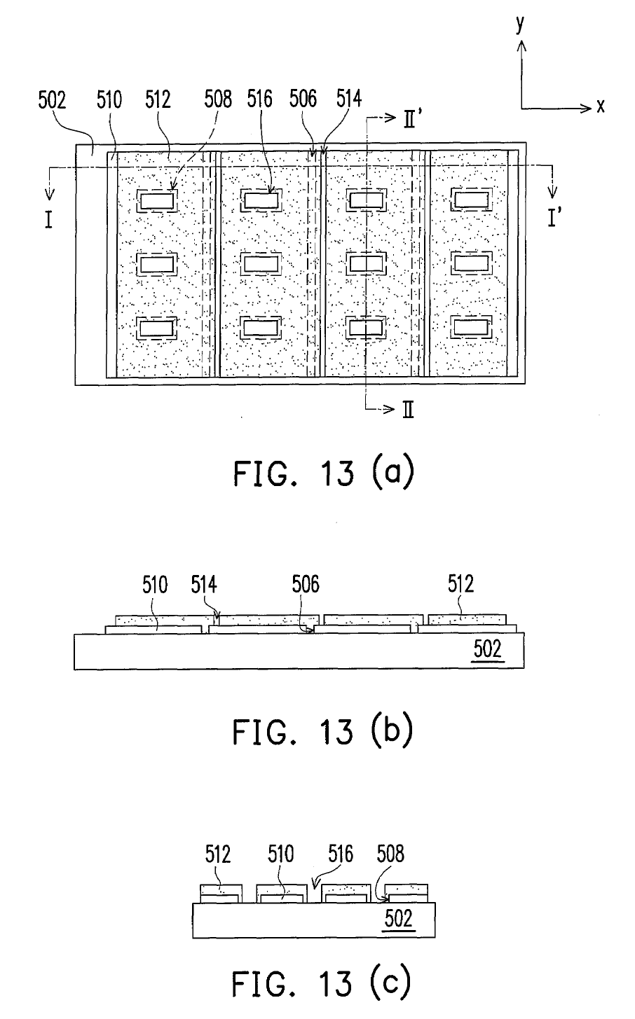

Please refer to FIGS. 13(a), 13(b) and 13(c). A portion of the photoelectric conversion layer 512 is removed to form a plurality of Y-directional openings 514 and a plurality of X-directional openings 516. Herein, the plurality of Y-directional openings 514 are formed above the window electrode 510 and are parallel to the Y-directional openings 506. Further, the x-directional openings 516 arranged in a two-dimensional array are formed in the X-directional openings 508.

During this step of the fabrication process, a portion of the photoelectric conversion layer 512 can be removed to merely form a plurality of Y-directional openings 514 but not the X-directional openings 516 shown in FIGS. 13(a), 13(b) and 13(c). The above-mentioned embodiment is omitted from the attached figures because anybody of ordinary skill in the art would have known such modification.

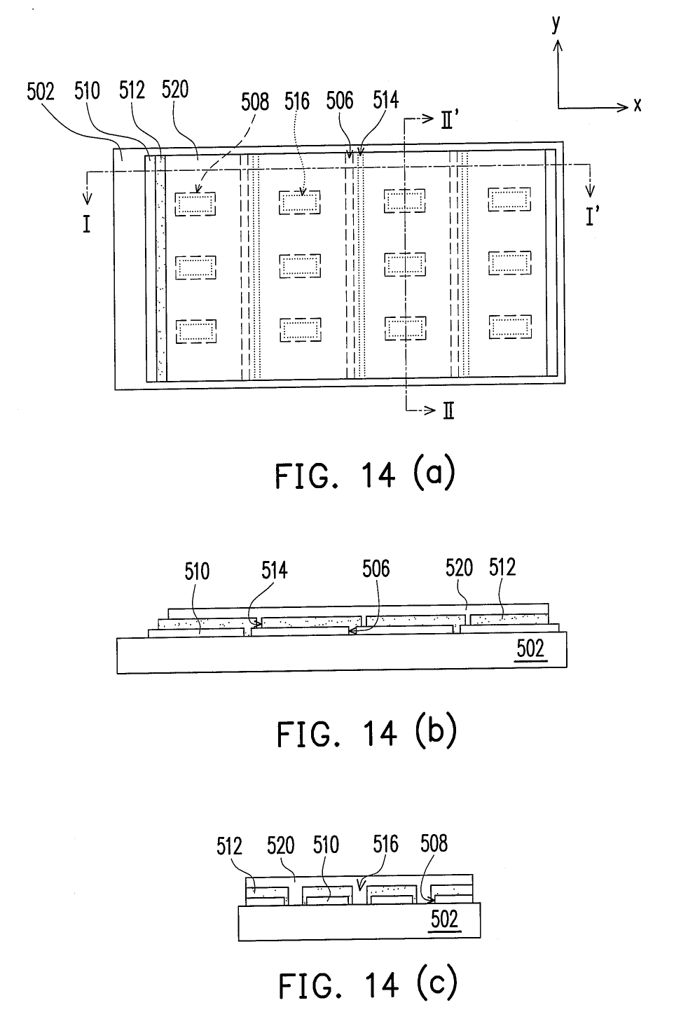

Please refer to FIGS. 14 (a), 14 (b) and 14(c). An electrode material layer 520 is formed above the transparent substrate 502. This electrode material layer 520 is a metal layer. Further, the photoelectric conversion layer 512, the window electrode 510 and the transparent electrode 502 will be covered by the electrode material layer 520.

Please refer to FIGS. 15 (a), 15 (b) and 15(c). A plurality of Y-directional openings 522 and a plurality of X-directional openings 524 are formed to divide the electrode material layer 520 into a plurality of window electrodes 526. Herein, the Y-directional openings 522 are formed by removing a portion of the electrode material layer 520 and a portion of photoelectric conversion layer 512 to expose the surface of the window electrode 510. The X-directional openings 524 are formed by removing a portion of the electrode material layer 520 in the X-directional openings 516. The thin film solar cell module of see-through type 500 in the present embodiment is completed after each step as mentioned above has been performed. In view of the above, if the last step involves only the formation of the Y-directional openings 514, then the X-directional openings 524 are formed by removing a portion of the electrode material layer 520 in the X-directional openings 516 and a portion of the photoelectric conversion layer 512.

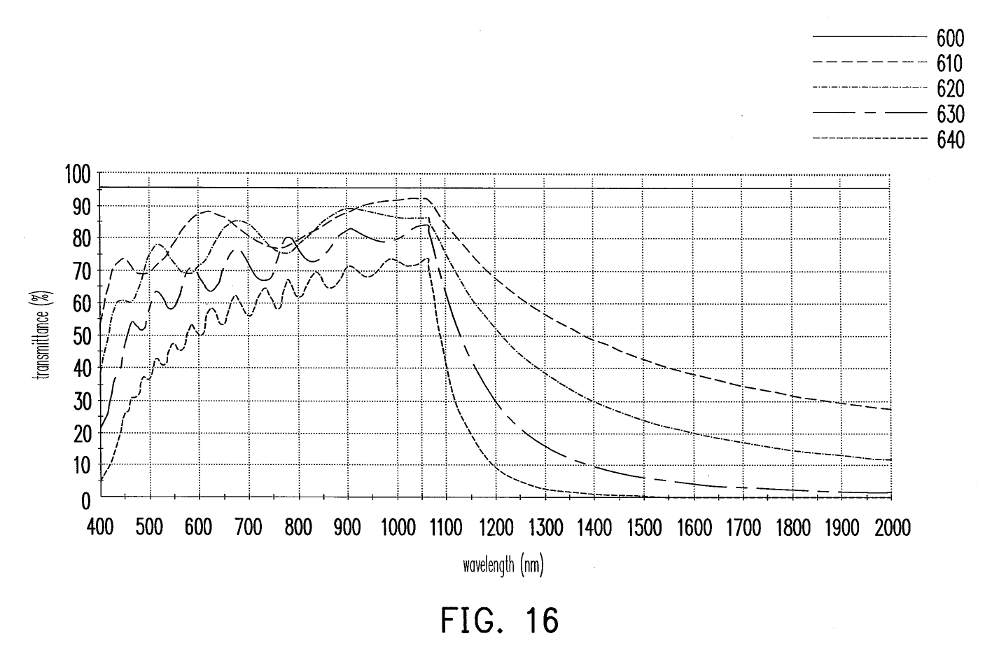

FIG. 16 is a graph illustrating the relationship between the transmittance through transparent electrodes of varying thickness disposed on a glass substrate and different wavelengths. FIG. 16 is produced based on the results of transmittance obtained by computer simulation which varies the thickness of ITO disposed on a glass substrate as a transparent electrode and the wavelength of light transmitted. Herein, the thickness of ITO for curves 610, 620, 630 and 640, respectively are 300 nm, 500 nm, 1000 nm, and 2000 nm. It should be noted that curve 600 is obtained based on a computer simulation where no transparent electrode was disposed on the glass substrate. According to FIG. 16, the transmittance for curve 600 is approximately 95%, and the respective transmittance for curves 610 620, 630 and 640 vary according to the thickness of ITO. The thicker the ITO, the lower the transmittance. Based on the above-mentioned simulation results, the thin film solar cell module of see-through type according to the present invention includes openings that can expose the transparent substrate. As a result, when light is transmitted through the bottom of the transparent substrate, the present invention has a higher transmittance compared to the conventional thin film solar cell module of see-through type.

Accordingly, the thin film solar cell module of see-through type and the method for fabricating the same according to the present invention forms bi-directional openings when forming the first electrode. Therefore, the thin film solar cell module of see-through type fabricated according to the present invention can overcome the problems such as short-circuit and current leakage resulted by the high-temperature laser scribing process. Hence, the production yield and the efficiency of the solar cell are improved. Furthermore, in contrast to the conventional thin film solar cell module of see-through type, the present invention includes openings that can expose the transparent substrate, which can greatly improve the transmittance of the cell module.

Although the present invention has been disclosed above by the embodiments, they are not intended to limit the present invention. Anybody skilled in the art can make some modifications and alteration without departing from the spirit and scope of the present invention. Therefore, the protecting range of the present invention falls in the appended claims.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a thin film solar cell module of see-through type, comprising:
forming a first electrode material layer on a transparent substrate;
removing a portion of the first electrode material layer to form a plurality of first Y-directional openings, which divide the first electrode material layer into a plurality of banding electrode material layers, and forming a plurality of first X-directional openings intersect with the plurality of the first Y-directional openings, which further divide the first electrode material layer into a first comb electrode and a two-dimensional array of multiple first electrodes;
forming a photoelectric conversion layer, which covers the transparent substrate, the first electrodes and a portion of the first comb electrode;
removing a portion of the photoelectric conversion layer to form a plurality of second Y-directional openings which are parallel to the first Y-directional openings above the first electrode;
forming a second electrode material layer, which covers the photoelectric conversion layer, the first electrodes and the transparent electrode; and
removing a portion of the second electrode material layer and a portion of the photoelectric conversion layer to form a plurality of third Y-directional openings that expose the surface of the first electrodes, and forming a plurality of second X-directional openings in the first X-directional openings to divide the second electrode material layer into a second comb electrode and a two-dimensional array of multiple second electrodes.

2. The method of claim 1, further comprising forming a plurality of third X-directional openings in the first X-directional openings when forming the second Y-directional openings by removing a portion of the photoelectric conversion layer.

3. The method of claim 2, wherein the third X-directional openings are formed by a laser scribing process.

4. The method of claim 1, wherein the first Y-directional openings, the second Y-directional openings, the third Y-directional openings, the first X-directional openings, and the second X-directional openings are formed by a laser scribing process.

5. The method of claim 1, wherein the first electrode material layer is a transparent conductive oxide layer.

6. The method of claim 1, wherein the photoelectric conversion layer is a single-layered structure or a multi-layered structure.

7. The method of claim 1, wherein the materials for fabricating the photoelectric conversion layer comprise amorphous silicon and amorphous silicon alloy, CdS, CulnGaSe₂ (CIGS), CulnSe₂ (CIS), CdTe, or organic material.

8. The method of claim 1, wherein the second electrode material layer is a metal layer.

9. A thin film solar cell module of see-through type having a plurality of cells connected in series and a plurality of openings formed among the cells to expose a transparent substrate, the thin film solar cell module comprising:
a first electrode disposed on the transparent substrate, and the first electrode is composed of a first comb electrode and a two-dimensional array of multiple first electrodes;
a second electrode disposed above the first electrode and the second electrode is composed of a second comb electrode and a two-dimensional array of multiple second electrodes,
wherein the second comb electrode and the first comb electrode are disposed symmetrically, and the first electrode and the second electrode are disposed by parallel displacement; and
a photoelectric conversion layer disposed between the first electrode and the second electrode, and the photoelectric conversion layer is composed of a two-dimensional array of multiple photoelectric conversion material layers.

10. The thin film solar cell module of see-through type of claim 9, wherein the first electrode is a transparent conductive oxide layer.

11. The thin film solar cell module of see-through type of claim 9, wherein the photoelectric conversion layer is a single-layered structure or a multi-layered structure.

12. The thin film solar cell module of see-through type of claim 9, wherein the materials for fabricating the photoelectric conversion layer comprise amorphous silicon and amorphous silicon alloy, CdS, CulnGaSe₂ (CIGS), CulnSe₂ (CIS), CdTe, or organic material.

13. The thin film solar cell module of see-through type of claim 9, wherein the second electrode is a metal layer.

14. A method for fabricating a thin film solar cell module of see-through type, comprising:
forming a first electrode material layer is on a transparent substrate;
removing a portion of the first electrode material layer to form a plurality of first Y-directional openings, which divide the first electrode material layer into a plurality of banding electrode material layers, and forming a plurality of first X-directional openings that intersect with the plurality of the first Y-directional openings, which divide the first electrode material layer into a plurality of first window electrodes;
forming a photoelectric conversion layer, which covers the first window electrode and the transparent substrate;
removing a portion of the photoelectric conversion layer to form a plurality of second Y-directional openings that are parallel to the first Y-directional openings above the first window electrode;
forming a second electrode material layer on the photoelectric conversion layer; and
removing a portion of the second electrode material layer and a portion of the photoelectric conversion layer to form a plurality of third Y-directional openings that expose the surface of the first window electrodes, and forming a plurality of second X-directional openings in the first X-directional openings to divide the second electrode material layer into a plurality of second window electrodes.

15. The method of claim 14, further comprising forming a plurality of third X-directional openings in the first X-directional openings when forming the second Y-directional openings by removing a portion of the photoelectric conversion layer.

16. The method of claim 14, wherein the first Y-directional openings, the second Y-directional openings, the third Y-directional openings, the first X-directional openings, the second X-directional openings, and the third X-directional openings are formed by a laser scribing process.

17. The method of claim 14, wherein the first electrode material layer is a transparent conductive oxide layer.

18. The method of claim 14, wherein the photoelectric conversion layer is a single-layered structure or a multi-layered structure.

19. The method of claim 14, wherein the materials for fabricating the photoelectric conversion layer comprise amorphous silicon and amorphous silicon alloy, CdS, CulnGaSe₂ (CIGS), CulnSe₂ (CIS), CdTe, or organic material.

20. The method of claim 14, wherein the second electrode material layer is a metal layer.

21. A thin film solar cell module of see-through type having a plurality of cells connected in series in the X-direction and connected in parallel in the Y-direction, and a plurality of openings formed among the cells to expose a transparent substrate, the thin film solar cell module comprising:
a first electrode disposed on the transparent substrate and the first electrode is composed of a plurality of first window electrodes;
a second electrode disposed on the first electrode and the second electrode is composed of a plurality of second window electrodes,
wherein the second window electrode and the first window electrode are disposed by parallel displacement; and
a photoelectric conversion layer disposed between the first electrode and the second electrode, and the photoelectric conversion layer is composed of a plurality of window photoelectric conversion material layers.

22. The thin film solar cell module of see-through type of claim 21, wherein the first electrode material layer is a transparent conductive oxide layer.

23. The thin film solar cell module of see-through type of claim 21, wherein the photoelectric conversion layer is a single-layered structure or a multi-layered structure.

24. The thin film solar cell module of see-through type of claim 21, wherein the materials for fabricating the photoelectric conversion layer comprise amorphous silicon and amorphous silicon alloy, CdS, CulnGaSe₂ (CIGS), CulnSe₂ (CIS), CdTe, or organic material.

25. The thin film solar cell module of see-through type of claim 21, wherein the second electrode is a metal layer.
